(19) United States
(12) Patent Application Publication
(10) Pub. No.: US 2011/0123036 A1
(43) Pub. Date: May 26, 2011

(54) MUFFLED RACK AND METHODS THEREOF

(76) Inventors: Yossi Barath, Herzelia (IL); Yoel Naor, Kibbutz Naan (IL); Michael Surov, Tel Aviv (IL); Alon Slapak, Mazor (IL)

(21) Appl. No.: 12/951,113

(22) Filed: Nov. 22, 2010

Related U.S. Application Data
(63) Continuation-in-part of application No. 11/606,010, filed on Nov. 30, 2006, now Pat. No. 7,869,607.
(60) Provisional application No. 60/778,090, filed on Mar. 2, 2006.
(60) Provisional application No. 60/778,091, filed on Mar. 2, 2006.

(51) Int. Cl. G10K 11/16; H05K 5/00; H05K 7/20

(52) U.S. Cl. 381/71.3; 454/184

(57) ABSTRACT

Some demonstrative embodiments include a muffled rack configured to maintain at least one electronic device, wherein the electronic device has an inlet to receive air for cooling the electronic device and an outlet to discharge the air. The muffled rack may be configured to muffle noise emanating from within the rack through an air inlet and/or an air outlet of the rack. Other embodiments are described and claimed.

### CROSS-REFERENCE

This application is a Continuation in Part of U.S. patent application Ser. No. 11/606,010, entitled “Quiet Active Fan for Servers Chassis”, filed Nov. 30, 2006, which claims the benefit of and priority from both U.S. Provisional Patent application No. 60/778,090, entitled “Quiet Active Fan for Servers Chassis”, filed Mar. 2, 2006 and U.S. Provisional Patent application No. 60/778,091, entitled “Soundproof Climate Controlled Rack”, filed Mar. 2, 2006, the entire disclosures of all of which are incorporated herein by reference.

### BACKGROUND

Noise in general, and tonal noise in particular is very annoying. Low-frequency noise is very penetrating, travels very long distances and is difficult to attenuate using traditional passive control measures.

Passive noise control technology, which usually involves using absorptive materials or noise partitions, enclosures, barriers and silencers, can be bulky, ineffective and rather expensive at low frequencies. Active Noise Control (ANC), on the other hand, can be very efficient and relatively cheaper in reducing low-frequency noise.

Active Noise Control (ANC) is a technology using noise to reduce noise. It is based on the principle of superposition of sound waves. Generally, sound is a wave is traveling in space. If another, second sound wave having the same amplitude but opposite phase to the first sound wave can be created, the first wave can be totally cancelled. The second sound wave is named “antinoise”.

As electric/electronic devices get smaller and functional, the noise of cooling devices becomes important. The noise from a computer that annoys people is mostly due to cooling fans if the hard drive(s) is fairly quiet. For example, there may be three (or more) fans inside a desktop computer. Usually there is a fan on the heat sink of the CPU, in the rear of the power supply unit, on the case ventilation hole, and maybe on the graphics card, plus one on the motherboard chipset. Most modern CPUs cannot function even for several seconds without a cooling fan, and some CPU's (such as Intel's Prescott core) have extreme cooling requirements, which often cause more and more noise. The type of fan used in a desktop computer is almost always an axial fan, while centrifugal fans are commonly used in laptop computers.

In many cases, for example, in blade chassis, RAID storage devices and the like (referred to herein as blade chassis) the noise level may exceed the level allowed according to the safety standards and regulations and in radical situations may even harm health. The noise emitted from standard fans normally used in blade chassis is characterized by one or several tones, such as at the low frequencies range (<1000 Hz). Attempts were made to reduce the noise by passive treatment, for example, IBM 49P2694 Acoustic Attenuation Module. In order to reduce low frequencies range (<1000 Hz) by means of passive treatment a substantial weight and size of material must be used. For example, to reduce a tone at 500 Hz by about 10 dBA, a muffler of a length of more than 1 meter and a diameter of 30 centimeter should be used. The passive means, which are currently being used, are not efficient for reduction of noise at low frequencies, particularly when dealing with fan noise involving airflow which cannot be blocked, without undesirable results (such as heat retention).

Servers can be deployed in two different manners, the traditional tower server chassis, or a rack-mountable chassis. For years tower servers were the standard, but over the past few years, rack-mounting servers has become very popular because it allows for increased manageability, consolidation, security, expansion and modularity, helping to lower the cost of deploying servers.

Some believe that rack-mounting servers is something that only makes sense for the largest companies, with mainframes and huge “glass house” data centers. In reality, anyone can take advantage of rack mounting servers and gain their benefits.

Racks are measured in rack units or “U's”; each U is 1.75″ high. The most popular racks are available in two heights—a 24U short rack and a 42U full rack. Computer companies offer a variety of servers to be mounted inside the racks in sizes varying from 1U through 5U. The most popular being the rack-dense 1U and 2U servers.

The primary reason for the growth of the rack mounting servers market is that data center space is either scarce, expensive, or both for most organizations; so whether customers build their own data centers or lease space from a service provider, companies must maximize their return by deploying as many servers as possible in the smallest space possible.

These factors have made 1U and 2U servers particularly attractive. Moving forward, servers will get even denser with the advent of Server Blades and Modular Blades. With this increased density, however, comes increasing power and thermal concerns as data center managers struggle with the ability to power and cool these rack-dense configurations.

The ultimate temperatures seen by internal server components will vary from server to server depending on the configuration, application, position in the rack, position in the data center, the amount of cabling, etc. Modern servers are designed to cool from front to back and are tested to meet elevated temperatures exceeding what is commonly found even in the worst-case locations in a data center. Conventional servers are designed for a 35° C. (95° F.) inlet temperature (into the front server surface) at maximum component power dissipations. This means that when run at full load, internal components are maintained below their recommended guidelines, or below the more stringent guidelines imposed by the manufacturer.

In a redundantly cooled system, the components meet these temperature requirements even in the event of a fan failure. With processors, servers are usually designed to cool to meet the requirements of future processor speeds, up to the maximum speed expected (based on the Intel specification). So, for a server component to exceed allowable operating temperatures, the server must be operating at maximum power (a maximized application, maximum processor speed) in an environment exceeding 35° C. (95° F.). Since most data centers are cooled to the low 20° C. (68° F.) range, there should be significant margin.

Traditional data center racks cool from the bottom up, taking in cool air being pumped into the data center through a raised floor. Other servers are designed to cool front to back, allowing them to be used in any environment. What matters for racks thermal concerns is that there is adequate airflow for cooling. The rack doors are perforated to allow for air flow, helping to cool systems

High-density servers often have reduced system airflow due to the added impact of the rack, cables, and cable management arm. Factors for system-reduced airflow include blockage due to cable management arms; blockage due to cables; rack doors, and the like.

The relying on airflow for cooling the dense servers, obliging the use of active devices to produce enough air movement lengthwise the electronic cards at all, and particularly around the processors, hard-drives, power devices, etc. These active devices are in most of the cases fans or blowers, which differ only by their blades configuration. The fans or the blower may be mounted anywhere in the dense server, but should obey several thermal guidelines to produce an efficient airflow around any important device in the unit.

Most of the modern racks mounting servers' fans/blowers are designed to produce a front to back cooling airflow. This is most effective when several similar dense servers are mounted together in a single dedicated chassis. The chassis, which is then being installed to the rack, prevents air to stream to any direction besides from the front panel to the back panel.

Most rack-mount equipment is designed with the fans/blowers placed in front and back; likewise, most rack enclosures are designed for a front-to-back airflow. Unfortunately, the heat dissipation resulting from the interior equipment fans is insufficient for coping with the amount of heat produced by modern servers. This concern involves auxiliary fans to be mounted at the panel of the rack and producing additional pressure to increase heat dissipation capacity.

Rack mounting servers are major noise sources and produce noise level of more then 80 dBA, which is regarded as very loud noise. Conservative solutions are based on sealing the rack with barrier materials such as steel tin, rubber sheets, etc, and lining of absorbing materials on the interior side of the rack panels. This procedure may cause thermal problems by restricting the airflow, and preventing efficient heat dissipation. The problem is usually being solved by adding auxiliary quiet blowers at the top of the rack or on one of its walls, and arranging an acoustic muffler at the air inlet. Unluckily, quiet blowers are accompanied by poor airflow capacity, and acoustic mufflers are designed to block noise by turning the air in different angles and hence reducing its velocity. The muffler operation results in additional impact to the airflow capacity.

### SUMMARY

Some demonstrative embodiments include a muffled rack configured to maintain at least one electronic device, wherein the electronic device has an inlet to receive air for cooling the electronic device and an outlet to discharge the air. The muffled rack may be configured to muffle noise emanating from within the rack through an air inlet and/or an air outlet of the rack.

In some demonstrative embodiments, the rack may include a first rack portion configured to surround at least the inlet of the device; a second, muffled, rack portion fluidly connected to the first rack portion to convey cooling air from a rack air inlet into the first rack portion and to muffle noise emanating from within the rack through the rack air inlet; and a third, muffled, rack portion configured to convey the air discharged from the outlet of the device to a rack air outlet, and to muffle noise emanating from within the rack through the rack air outlet.

In some demonstrative embodiments, the first, second and third rack portions may be configured to cause the cooling air to flow from the rack air inlet, through the second, muffled, rack portion, through the first rack portion, and into the inlet of the device; and to cause the air discharged from the outlet of the device to flow through the third, muffled, rack portion and out of the rack air outlet.

In some demonstrative embodiments, the rack may be configured to maintain the electronic device such that the inlet of the device faces a first direction and a the outlet of the device faces a second direction, wherein the second rack portion includes at least one inlet duct configured to discharge the cooling air into the first rack portion in a direction substantially perpendicular to the first direction.

In some demonstrative embodiments, the rack may include a chamber substantially perpendicular to the inlet duct and fluidly connected to the outlet of the device; and at least one outlet duct substantially parallel to the inlet duct to convey air from the chamber to the rack air outlet.

In some demonstrative embodiments, the first rack portion may include a chamber substantially perpendicular to the inlet duct and fluidly connected to the inlet of the device.

In some demonstrative embodiments, the first rack portion may be configured to surround the device.

In some demonstrative embodiments, the rack may include a fan to convey the air discharged from the outlet of the device into the third rack portion.

In some demonstrative embodiments, the rack air inlet and the rack air outlet may be positioned on different sides of the rack.

In some demonstrative embodiments, the rack air inlet and the rack air outlet may be positioned on opposite sides of the rack.

In some demonstrative embodiments, at least one of the second and third rack portions may include a duct.

In some demonstrative embodiments, at least one of the second and third rack portions may include an active noise cancellation (ANC) system.

In some demonstrative embodiments, a muffled rack may include a rack air inlet to receive cooling air; a rack air outlet to discharge air from the rack; a first chamber to provide the cooling air to the inlet of the device; at least one inlet muffled duct to convey the cool air from the rack air inlet into the first chamber and to muffle noise emanating from within the first chamber through the rack air inlet; a second chamber to maintain the air discharged from the outlet of the device separate from the air in the first chamber; and at least one outlet muffled duct to convey the air from the second chamber to the rack air outlet and to muffle noise emanating from within the first chamber through the rack air outlet.

In some demonstrative embodiments, the first chamber may be configured to maintain the device at a predefined orientation such that the inlet of the device faces a first predefined direction, and wherein the inlet duct may be configured to discharge the cool air at a second direction, substantially perpendicular to the first direction.

In some demonstrative embodiments, the inlet and outlet ducts may be located on opposite sides of the first chamber, and wherein the second chamber may be perpendicular to the inlet and outlet ducts.

In some demonstrative embodiments, the rack air inlet and the rack air outlet may be positioned on different sides of the rack.

In some demonstrative embodiments, the rack air inlet and the rack air outlet may be positioned on opposite sides of the rack.

In some demonstrative embodiments, the rack may include at least one fan to convey the cool air from the rack air inlet into the first chamber.

In some demonstrative embodiments, the rack may include at least one fan to convey the air from the second chamber to the rack air outlet.

In some demonstrative embodiments, at least one of the inlet and outlet ducts may include an active noise cancellation (ANC) system.

In some demonstrative embodiments, the at least one electronic device may include at least one server.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of a rack, in accordance with some demonstrative embodiments.

FIG. 2 is a schematic block diagram illustration of an Active Noise Control (ANC) system, in accordance with some demonstrative embodiments.

FIG. 3 is schematic block diagram illustration of an ANC controller, in accordance with some demonstrative embodiments.

FIG. 4 is a schematic block diagram illustration of example of a duct mounting, in accordance with some demonstrative embodiments.

FIG. 5 is a schematic block diagram illustration of three ducts soundproof climatic controlled panels installed on a rack, in accordance with some demonstrative embodiments.

FIG. 6 is a schematic block diagram illustration of a thermal control unit incorporated into a duct, in accordance with some demonstrative embodiments.

FIG. 7 is a schematic flow-chart illustration of a method for reducing the effects of a noise source, in accordance with some demonstrative embodiments.

FIG. 8 is a schematic flow-chart illustration of a method for thermal control, in accordance with some demonstrative embodiments.

FIG. 9 is a schematic block diagram illustration of a rack, in accordance with some demonstrative embodiments.

### DETAILED DESCRIPTION

In the following detailed description, numerous specific details are set forth in order to provide a thorough understanding of some embodiments. However, it will be understood by persons of ordinary skill in the art that some embodiments may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality” as used herein include, for example, “multiple” or “two or more”. For example, “a plurality of items” includes two or more items.

In some embodiments, there is provided a method for reducing noise in a server chassis such as blade server/center chassis by combining passive and active reduction of noise.

In some embodiments, there is provided a soundproof and/or climatic controlled rack and/or panel, e.g., as described below.

The term “muffled” as used herein with respect to an element may refer to an element configured to suspend, partially or entirely, to reduce, partially or entirely, to decrease partially or entirely, to diminish, partially or entirely, to block, partially or entirely, and/or to eliminate a level of noise and/or sound. For example, a muffled rack may include a rack configured to suspend, partially or entirely, to reduce, partially or entirely, to decrease partially or entirely, to diminish, partially or entirely, to block, partially or entirely, and/or to eliminate a level of noise, originating, emanating and/or generated from one or more elements within the rack. A muffled duct may include a duct configured to suspend, partially or entirely, to reduce, partially or entirely, to decrease partially or entirely, to diminish, partially or entirely, to block, partially or entirely, and/or to eliminate a level of noise carried by air traveling through the duct. The muffling may be achieved, for example, using any suitable passive noise reduction, any suitable active noise reduction, or any combination thereof, e.g., as described herein.

The term “Soundproof” as used herein may have the meaning of not penetrable by audible sound, partially penetrable by audible sound, and/or having reduced penetration of audible sound.

The phrase “Soundproof panel” may refer to a panel (such as a component of a rack), which may be adapted to prevent or reduce the penetration of audible sound such as noise.

The phrase “Soundproof cooling unit” may refer to a drawer like unit, which may be installed in a rack as any other device, basically as the upper device and/or the lower device, which may be adapted to prevent or reduce the penetration of audible sound such as noise.

The phrase “Climatic controlled” may refer to having regulated and/or managed effect on climate, for example, temperature, humidity and/or airflow condition.

The phrase “Climatic controlled panel” may refer to a panel (such as a component of a rack), which may be adapted to control, regulate and/or manage the climate.

In some demonstrative embodiments, the soundproof climatic controlled wall (or panel or cooling unit) may include one or more auxiliary fans or blowers. The one or more auxiliary fans or blowers may provide airflow capacity to cope with heat dissipation which may be measured in some cases as power consumption, of up to 12 kilowatt (kW). Furthermore, the soundproof climatic controlled wall (or panel or cooling unit) may provide a noise reduction of up to 20 dBA or more. The abbreviation “dBA” may refer to decibels adjusted and may also be referred to as dBm adjusted. The abbreviation “dBA” may refer to a weighted absolute noise power, calculated in dB referenced to 3.16 picowatts (−85 dBm (referenced to one milliwatt)).

In some demonstrative embodiments, the soundproof climate controlled panel may replace or augment one or more of the six or more panels of a rack including, but not limited to, one or more door(s), wall(s), floor(s) or roof(s), or may be installed in the rack as any other device, basically as the upper device and/or the lower device, like a drawer with a connection to a one or more inlet/outlet openings in one or more of the six or more panels of a rack.

The installation configuration may be derived from the required airflow regime. Heavy-duty racks may require more than one soundproof climatic controlled panel which may then, for example, be installed at a different direction of the fans and serve as air inlet as well as air outlet.

In some demonstrative embodiments, there is also provided a rack, which may include one or more soundproof climatic controlled panel(s). The soundproof climatic controlled wall (panel or cooling unit) may include one or more auxiliary fans or blowers. The one or more auxiliary fans or blowers may provide airflow capacity to cope with heat dissipation of up to 12 kW. Furthermore, the soundproof climatic controlled wall may provide a noise reduction of up to 20 dBA or more.

In some demonstrative embodiments, the panel and/or rack as referred to herein may provide more than 6 kW heat dissipation while 2 blade servers are installed. The rack as referred to herein may provide about 15 dBA reduction of the equipment noise.

In some demonstrative embodiments, the noise reduction may be achieved by at least one or more of:
Passive noise reduction, for example: quiet structure(s), for example: strengthening to the rack panels, maze like structure of the air inlet, the air outlet and/or the cable(s) openings; absorbing materials, for example: sponges, wool and any other acoustic absorbing compound; isolation materials, for example: stratified structure of the walls and seals; vibration damping techniques, for example: shock absorbers associated with the fans, elastic hinges and/or elastic feet, and the like.

In some demonstrative embodiments, the climate control system may include one or more of controllable fan operation regarding temperature, pressure, fan failures and humidity. The climate control system may accelerate (increase) or decelerate (decrease) the fan's velocity based on the heat dissipation needs, which may be computed regarding the temperature and the interior pressure. This control may yield a significant power saving, and may also reduce noise, which is generated and needs to be suppressed.

In some demonstrative embodiments, the control system may warn the user when fan fault appear to occur or may occur, hence to prevent damage to the equipment.

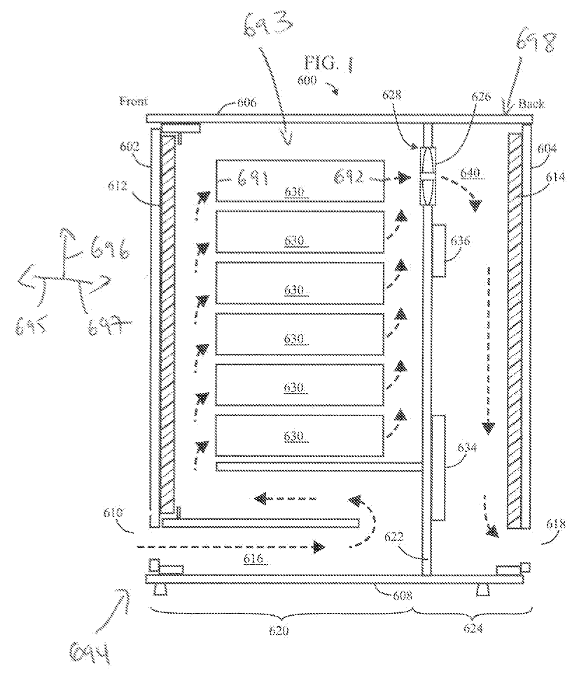

FIG. 1 illustrates (in cross-section) an example of a rack (cabinet) 600.

In some demonstrative embodiments, rack 600 may include a muffled rack configured to maintain at least one electronic device 630, e.g., one or more severs, having an inlet 691 to receive air for cooling electronic device 630 and an outlet 692 to discharge the air.

In some demonstrative embodiments, rack 600 may include a first rack portion 693 configured to surround at least the inlet 691 of device 630, e.g., as described in detail below.

In some demonstrative embodiments, rack 600 may include a second, muffled, rack portion 694 fluidly connected to first rack portion 693 to convey cooling air from a rack air inlet 610 into first rack portion 693. Rack portion 694 may be configured to direct the cooling air towards the inlet 691 of device 630, e.g., as described in detail below.

In some demonstrative embodiments, rack 600 may include a third, muffled, rack portion 698 configured to convey the air discharged from the outlet 692 of device 630 to a rack air outlet 618.

In some demonstrative embodiments, rack portion 694 may be configured to muffle noise emanating from within rack 600, e.g., from within portion 693, through rack air inlet 610; and/or rack portion 698 may be configured to muffle noise emanating from within rack 600, e.g., from within portion 693, through rack air outlet 618, e.g., as described in detail below.

In some demonstrative embodiments, rack portion 698 may be configured to reduce and/or eliminate mixture of the air discharged from the outlet 692 with the cooling air from the rack air inlet 610. In one example, rack portion 698 may include a chamber having an inlet positioned in proximity to outlet 692, e.g., as described in detail below.

In some demonstrative embodiments, at least one of rack portions 694 and 698 may include a duct, e.g., as described in detail below.

In some demonstrative embodiments, rack 600 may be configured to cause the cooling air to flow from rack air inlet 610, through the second, muffled, rack portion 694, through the first rack portion 693, and into the inlet 691 of device 630; and to cause the air discharged from the outlet 692 of device 630 to flow through the third, muffled, rack portion 698 and out of the rack air outlet 618, e.g., as described in detail below.

In some demonstrative embodiments, rack 600 may be configured to maintain device 630 such that the inlet 691 of the device 630 faces a first direction 695 and the outlet of the device faces a second direction 697; and second rack portion 694 may include at least one inlet duct 616 configured to discharge the cooling air into the first rack portion 693 in a direction 696 substantially perpendicular to direction 695, e.g., as described in detail below.

In some demonstrative embodiments, first rack portion 693 may be configured to substantially surround the device 630, e.g., as described in detail below.

In some demonstrative embodiments, rack 600 may include one or more fans 626 to convey the air discharged from the outlet 692 of device 630 into the third rack portion 698, e.g., as described in detail below.

In some demonstrative embodiments, rack air inlet 610 and rack air outlet 618 may be positioned on different sides of the rack. For example, rack air inlet 610 and rack air outlet 618 may be positioned on opposite sides of rack 610, e.g., as described below.

In some demonstrative embodiments, at least one of rack portions 694 and 698 may include a duct, e.g., as described in detail below.

In some demonstrative embodiments, at least one of rack portions 694 and 698 may include an active noise cancellation (ANC) system, e.g., as described below.

In some demonstrative embodiments, rack 600 is generally a six-sided rectangular (prismatic) cabinet structure. For example, as shown in FIG. 1, a first side, e.g., a front, of rack 600 may have a door 602 and/or a second side, e.g., a back, of the rack, may have a door 604. Rack 600 may have a top wall 606, and a bottom wall 608. Rack 600 may have two sidewalls, not visible in the cross-section.

In some demonstrative embodiments, a soundproof material 612 may line the inside surface of the front door 602, and/or soundproof material 614 may line the inside surface of the back door 604.

In some demonstrative embodiments, the front door 602 may include an opening (air inlet) 610 leading to a channel 616 located at a bottom portion of the rack 600, in a front portion 620 of the rack 600. Airflow into the opening 610 and in the channel 616 is indicated by dashed-line arrows.

In some demonstrative embodiments, air inlet 610 may be provided with any suitable muffler.

In some demonstrative embodiments, front portion 620 of rack 600 may be separated by an interior wall 622 from a back portion 624 of the rack 600. The interior wall 622 extends from side-to-side, and from top-to-bottom.

In one demonstrative embodiment, interior wall 622 may generally be similar to the exterior back wall in a conventional prior art rack.

In some demonstrative embodiments, the interior “back” wall 622 is provided with an opening 628 through which air can escape from the front portion 620 of the rack 600.

In some demonstrative embodiments, airflow through the front portion 620 of the rack 600 is from front bottom to rear top.

In some demonstrative embodiments, cooling air enters the channel 616 through the opening 610 in the front door 602. The channel 616 may be labyrinthine (maze like), for example, first extending towards the back of the rack 600, then turning 180 degrees and extending towards the front of the rack 600, as illustrated. In this manner, cooling air will be available at the front(s) of the server(s) 630 (as if the front door 602 were open). The “maze” of the channel 616 is sometimes referred to as a “muffler”.

A number of (six, illustrated) rack-mounted servers 630 are illustrated, mounted in a conventional manner in the front portion 620 of the rack 600.

In some demonstrative embodiments, at least part of the front portion 620 of the rack 600, up to the interior “back” wall 622, my be of conventional design.

In some demonstrative embodiments, one or more fans 626 may be disposed in the opening 628 to assist in moving air from the front portion 620 of the rack to the back portion 624 of the rack (and, in a typical prior art rack where the wall 622 is the exterior wall, to outside of the rack). The fan 628 is optional.

In this example, at least part of back portion 624 of the rack 600 can be considered to be a soundproof, climatic-controlled back panel, rather than simply being a wall with a fan (626) in it.

In some demonstrative embodiments, the soundproof, climatic-controlled back panel 624 may be an add-on to, or a replacement for, the existing back panel (622) of a rack (600). (Without the climactic-controlled back panel 624, the back panel 622 would constitute an external surface of the rack 600.) As mentioned above, any of the panels (walls, external surfaces) of the rack 600 can be modified, as disclosed herein, to be a soundproof climatic controlled panel. The reference numeral “624” will be used to refer to the soundproof, climatic-controlled back panel, described herein. Later, examples will be given where the back panel 624 is a duct, or a plurality of ducts.

In some demonstrative embodiments, the soundproof climatic controlled panel 624 may include a channel 640 extending from the top of the rack 600 to the bottom of the rack 600, and from the interior back wall 622 of the rack 600 to the back door 604 of the rack 600.

In some demonstrative embodiments, the soundproof climatic controlled panel 624 may be a duct (other embodiments of ducts are described hereinbelow) which is generally rectangular prismatic shaped having six sides, an inlet opening at one end, and an outlet opening at an opposite end.

In some demonstrative embodiments, the channel 640 may have inlet opening 628, with optional fan 626, disposed near the top of the rack for receiving equipment-warmed air from the front portion 620 of the rack 600, and has outlet opening 618 disposed near the bottom of the back door 604 for expelling air from within the rack 600 to without the rack 600.

In some demonstrative embodiments, the soundproof climatic controlled panel 624 may include acoustic passive materials, such as the soundproof material 614 lining the inside surface of the back door 604. Acoustic passive material may be used on any/all of the interior surfaces of the channel 640.

Additionally or alternatively, the soundproof climatic controlled panel 624 may include inlet fans, such as the fan 626 disposed in the interior back wall 622 of the rack 600.

Additionally or alternatively, the soundproof climatic controlled panel 624 may include an ANC system 634, e.g., as described below, which may be disposed in the channel 640 and/or elsewhere in the rack 600.

Additionally or alternatively, the soundproof climatic controlled panel 624 may include a control system 636, e.g., as described below, which may be disposed in the channel 640 and/or elsewhere in the rack 600.

Some embodiments are described herein with reference to a rack, e.g., rack 600, including an inlet duct in the form of a channel, e.g., channel 616, configured to cause the cooling air to flow in a labyrinthine manner, e.g., as shown in FIG. 1; an outlet duct in the form of a channel, e.g., channel 640, which may be implemented in the form of an elongated chamber, e.g., as shown in FIG. 1; one or more fans, e.g., fans 626, to convey air into the outlet duct; and/or an ANC located in the outlet duct, e.g., ANC 634. However, other embodiments may include a rack including any suitable configuration and/or combination of one or more inlet ducts, one or more outlet ducts, one or more ANCs and/or one or more fans. For example, a rack may include an inlet duct in the form of a channel, e.g., similar to channel 640, which may be implemented in the form of an elongated chamber; an outlet duct in the form of a channel, e.g., similar to the form of channel 616, configured to cause the air to be discharged from the rack to flow in a labyrinthine manner; one or more fans, e.g., similar to fans 626, to convey air from the inlet duct toward the inlet of the device; an ANC, e.g., similar ANC 634, located in the inlet duct; and/or any other suitable combination. In some embodiments, a rack may include a combination of one or more inlet ducts, one or more chambers and/or one or more outlet ducts, e.g., as described below with reference to FIG. 9.

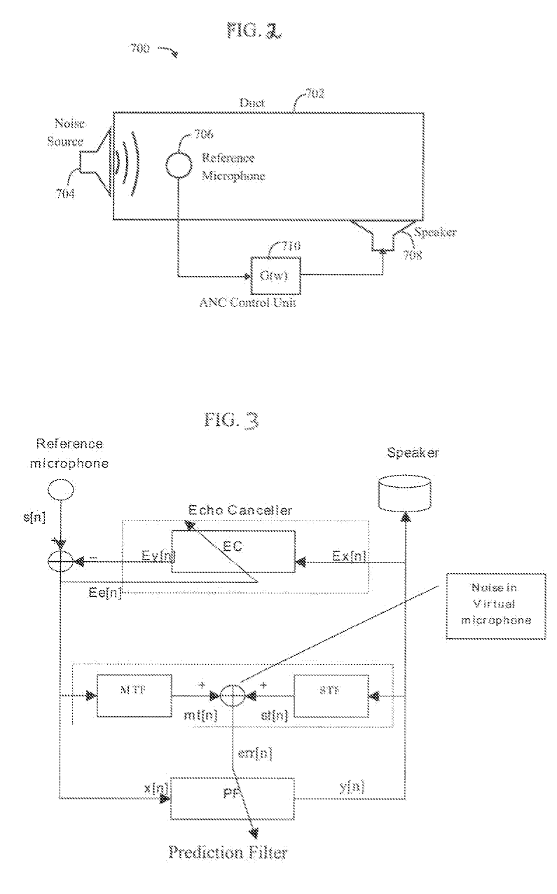

FIG. 2 illustrates an active noise control (ANC) system 700, in accordance with some demonstrative embodiments. In some embodiments, ANC system 700 may perform the functionality of ANC system 634 (FIG. 1).

In some demonstrative embodiments, the ANC system 700 is shown in conjunction with an elongated air duct 702 having an inlet end which is open (to the left of the figure) and an outlet end which is open (to the right of the figure). The air duct may 702 may have a round cross-section, or it may have a rectangular cross-section or any other configuration.

In some demonstrative embodiments, air duct 702 may be configured to convey air from a first location to a second location, from its inlet end to its outlet end.

In some demonstrative embodiments, air duct 702 may have an additional purpose, which is reducing noise, which may be emanating from the first location.

A noise source 704 is shown at the inlet end of the air duct 702.

In some demonstrative embodiments, the ANC system 700 includes an acoustic sensor (input transducer, such as a microphone) 706 that receives the noise to be reduced (destructed, suppressed reduced or cancelled). The acoustic sensor 706 may be referred to herein as “reference microphone”. The reference microphone 706 may be located anywhere within the duct 702, and may also be located outside of the duct 702.

In some demonstrative embodiments, the ANC system 700 includes an acoustic transducer (output actuator, such as a speaker) 708 that emits destructive (noise-canceling) noise (also referred to as “anti-noise”). The acoustic transducer 708 may be referred to herein simply as “speaker”. The speaker 708 may be located anywhere within the duct 702, and may also be located outside of the duct 702.

In some demonstrative embodiments, the ANC system 700 includes a controller (electronic system) 710, which calculates the destructive (noise-canceling) noise to be emitted by the speaker.

In some demonstrative embodiments, by monitoring the noise from the noise source 704 (using the microphone 706), anti-noise can be calculated by the controller 710 and emitted by the speaker 708 to reduce the noise.

In some demonstrative embodiments, noise-canceling techniques may include generating anti-noise, which is out of phase with the noise generated by the noise source, which can theoretically cancel the noise. Alternatively, anti-noise may be generated which shifts the frequency of the noise being generated by the noise source, such as from a low frequency (such as under 1000 Hz) to a higher frequency (such as over 1000 Hz).

In some demonstrative embodiments, a second microphone (not shown) can be provided to monitor the results of noise cancellation, at a given, monitored location, and the controller can control the anti-noise which is calculated so that the noise at the monitored location can better be minimized. Such a second microphone may be referred to as an “error microphone”. This configuration may include a control (or feedback) loop situation where a signal is calculated to effect a desired result, the result is monitored, and any deviations from the desired result are taken into account in recalculating the signal so as to better effect the desired result.

In some demonstrative embodiments, optionally, the controller 710 may also be used to control, directly or indirectly, the temperature and the pressure of the unit.

In some demonstrative embodiments, the Acoustic Noise Control (ANC) system may include an input transducer and an output actuator that are preferably physically located in unitary position, or at least, next to each other in the same location.

In one embodiment, the input transducer and the output actuator are a hybrid represented by a single element. The active noise reduction system may be located as close as possible to the noise source as possible and functions to generate the cancellation sound wave with minimum delay with respect to the noise source(s) and minimum reflection or distortion of the noise waveform(s).

In some demonstrative embodiments, the active noise control system, when located very close to the noise source(s), functions to generate synthetic sound waves having a phase preferably opposite that of the noise. Both the noise source and the active noise control system might be situated within an enclosure or may be situated external to an enclosure. In one embodiment, the noise sound wave and the cancellation sound wave spread almost from the same point producing a high amount of noise cancellation. The output power of the cancellation signal is chosen so as to achieve maximum cancellation of the noise sound.

In some demonstrative embodiments, the acoustic cancellation method implemented by the controller may be based on the behavior of acoustic beam patterns in air or other fluids.

In some demonstrative embodiments, cancellation of the noise is achieved in an area far from the noise source while in an area relatively close to the noise source there may be pockets of noise that exist. The length of the quiet zone, as measured from the noise source, is determined by the power of the cancellation signal generated and output by the system. Since the output acoustic beam pattern is dependent on the characteristics of the output actuator and on the main cancellation frequency that is used, the type of output actuator or the angle between a plurality of actuators may need to be varied in order to achieve optimum results for different noise frequencies. The noise reduction method may be capable of achieving effective cancellation of the noise when the surface of the noise source is complex given that the distance from the noise source to the point of cancellation is bigger then the length of the noise source itself.

In some demonstrative embodiments, the system may detect the sound from the output actuator, e.g., in addition to sensing sound from the noise source. The portion of the input signal that is due to the output actuator is removed as by using an echo cancellation technique. Using an echo cancellation system may be preferred, e.g., if the output and input transducers are acoustically separate elements and there exists acoustic delayed feedback in the system. Another advantage of the echo cancellation system is the elimination of feedback sound emanating from walls, furniture, etc. and sensed by the input transducer. A computation may be performed on the input signal, for example, instead of using an echo cancellation system, to discern the actual noise signal from the input signal, e.g., if there is no delayed time feedback from the output transducer to the input transducer and a directional input transducer is used.

In some demonstrative embodiments, the cancellation signal (destructive noise) generated by the output actuator may be reflected from the noise source itself thus adding to the amount of noise present. In order to eliminate this type of noise, a delayed cancellation signal is generated by the system. The delay and phase shift applied to the cancellation signal may be matched to the delay and phase shift associated with the reflection and feedback of the sound from the output actuator.

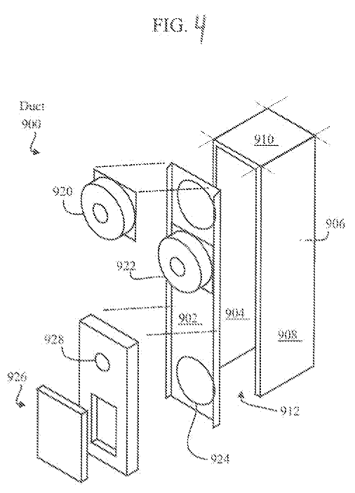

Reference is now made to FIG. 3, which illustrates an ANC controller, in accordance with some demonstrative embodiments. In some embodiments the ANC controller of FIG. 3 may be suitable for the ANC system of FIG. 2. The abbreviations used herein are short for: EC, echo cancellation; PF, prediction filter; MTF, reference microphone to error microphone transfer function; STF, speaker to error microphone transfer function.

In some demonstrative embodiments, there is provided an ANC system for reducing the effects of a noise source, including an input transducer for sensing the acoustic noise field generated by the noise source and for generating an input signal therefrom, an output actuator for generating an acoustic output field that is effective to reduce the level of the acoustic noise field, a correction module for adjusting the input signal generated by the input transducer to compensate for the nonlinear characteristics of the input transducer and output actuator, an echo cancellation module for removing from the input signal a portion of the output of the output actuator feedback through the input transducer, the output of the echo cancellation module representing a signal preferably corresponding to substantially the noise source by itself, an anti-noise module for generating an anti-noise signal opposite in phase to the input signal, the output actuator generating the acoustic output field from the anti-noise signal and wherein the input transducer may be located in relatively close proximity to the output actuator.

The echo cancellation module may include a digital filter having a delay line with a number of taps whose total delay time is equivalent to at least a system time delay of the noise reduction system, an adaptor for dynamically adjusting the coefficient values associated with each of the taps of the digital filter and a summer for adding the output of the digital filter with the output of the correction module.

The antinoise module may include the speaker and may include a variable gain amplifier which is located on the electronic board and which is operative to generate an amplified signal 180 degrees opposite in phase from the input signal and a gain controller for dynamically controlling the gain of the variable gain amplifier. The gain controller may be adapted to receive a manual input control signal from a user which determines the gain of the variable gain amplifier, the user able to vary the location of a quiet zone generated by the system by varying the input control signal. The input control signal is generated by the user remotely from the system and transmitted to the system via wireless communication signals.

The system may further include a low pass filter, which is located on the electronic board operative to reduce oscillations present in the system derived from feedback of the acoustic output field to the input transducer. Also, the system may further include a delay canceller as part of the algorithm executed by the controller for reducing the effect of echo signals caused by the anti-noise module sensed by the input transducer. The delay cancellator may include a plurality of delay cancellation circuits wherein one or more or each delay cancellation circuit is operative to reduce the effect of the echo caused by previous delay cancellation circuits.

A method for reducing the effects of a noise source may include sensing the acoustic noise field generated by the noise source and generating an input signal therefrom, generating an acoustic output field that is effective to reduce the level of the acoustic noise field, adjusting the input signal generated by an input transducer to compensate for non-linear characteristics of the input transducer, removing extraneous signals from the input signal so as to generate a signal corresponding to substantially the noise source alone and generating an anti-noise signal opposite in phase to the input signal, and generating the acoustic output field from the anti-noise signal.

Referring back to FIG. 1, fans 626 may serve as airflow generator device(s), which enforce or support the necessary heat dissipation capability. The fans may be mounted lengthwise of the duct as well as at the beginning of the duct. This is determined by the distribution of the heat sources in the rack. A fan may be mounted or focused against or towards any major heat source.

In some demonstrative embodiments, one or more fans and/or blowers (for example, Sanyo Denki—San Ace 200 mm or EBM R4E355AN) may be included in a duct. The fans may push air when the duct serves as an air outlet or pull the air when the duct serves as an air inlet. The fans may or may not be combined with a current regulator or the like, which enables the control system to control the fans' velocity.

In some demonstrative embodiments, the fan(s) may be mounted on shock absorber(s) such that the fans' Eigen (intrinsic) frequencies will not be passed to the soundproof panel and produce noise.

In some demonstrative embodiments, a duct of rack 600 may include any suitable acoustic absorbing material, which may serve as a passive noise reduction element. This material may be sponge, acoustic compound material, rock wool, mineral wool or any other known or developed acoustic absorbing material. The acoustic absorbing material may be secured, such as glued, to the interior surfaces of the duct. The acoustic absorbing material together with the duct shape acts to depress the high frequencies noise emitted trough the airflow path (either shifting the frequency to lower wavelength or suppressing/reducing the energy of such high frequency noise).

In some demonstrative embodiments, control System (636) may be adapted to control the fans' velocity according to the temperature and/or the pressure values in the rack. The control system 636 may sense the temperature and the pressure as via dedicated sensors, and may accelerate or decelerate the fans' velocity to achieve given values of the pressure and the temperature inside the rack. This control system 636 may yield power saving and long-term operation.

In some demonstrative embodiments, the system may be adapted to drive or trigger an alarm device when a fan fault is discovered for the sake of preventing damage to the interior devices. The fan fault is discovered as via the noise which may be sensed by a microphone such as one in the ANC system. When noise is below a given value at a given narrow frequencies band, which may depend upon the Eigen (intrinsic) frequencies of the fan, the control system may be adapted to trigger an alarm.

In some demonstrative embodiments, the Channel/Duct (640) may provide the following:
1. Maintaining the system parts at their exact place for example, the speaker, the microphone and/or the acoustic passive materials;
2. Serving as another layer of acoustic barrier: Since a significant part of the noise energy is emitted through the rack panels, the location of the duct onto the soundproof climatic controlled panel(s) may enhance blocking of acoustic energy by the panel. In addition to the thickening of the panel, which is also contributing to the isolation ability, and the construction of the duct with at least two sides perpendicularly to the panel surface may restrain the vibrations of the soundproof panel and thereby may block the sound energy which is emitted as vibrations of the panel;
3. Serving as an acoustic muffler: The length of the duct and its cross-section area may be designed to serve as an acoustic low-pass filter and to reduce the high-frequencies noise, which is accompanied to the airflow. The break frequency of the filter may comply with the ANC demands on one hand, and may avoid generation parasitic noise, which stems, for example, from the air rush through unfitted duct(s) cross-section on the other hand;
4. Merging the noise from the interior parts: The ANC system may deal at least with the low-frequencies noise emitted from the rack through the airflow path. This noise cannot be treated effectively via conventional passive means, since conventional methods (such as sound absorbing materials, discussed hereinabove) usually dramatically inhibit, limit or eviscerate the heat dissipation capability. The low frequency noise is combined with the interior devices noise (for example, blade servers, dense servers, power supplies) and the auxiliary fans noise. To better treat this noise by an ANC system, the noise may be merged to produce a significant coherence of the noise between any two consequent points. The configuration of the duct may be designed to serve this aim;

In some demonstrative embodiments, in the example of FIG. 1, the duct 640 extends the entire height of the rack 600, from top to bottom (as viewed), but may extend only partially along the width (from side-to-side, into the page, as viewed) of the back panel of the cabinet 600.

In some demonstrative embodiments, a number of ducts can be disposed in the panel. The number of the ducts, their dimensions and shapes may be designated or derived from the rack inner configuration, the characteristics of the noise and other parameters.

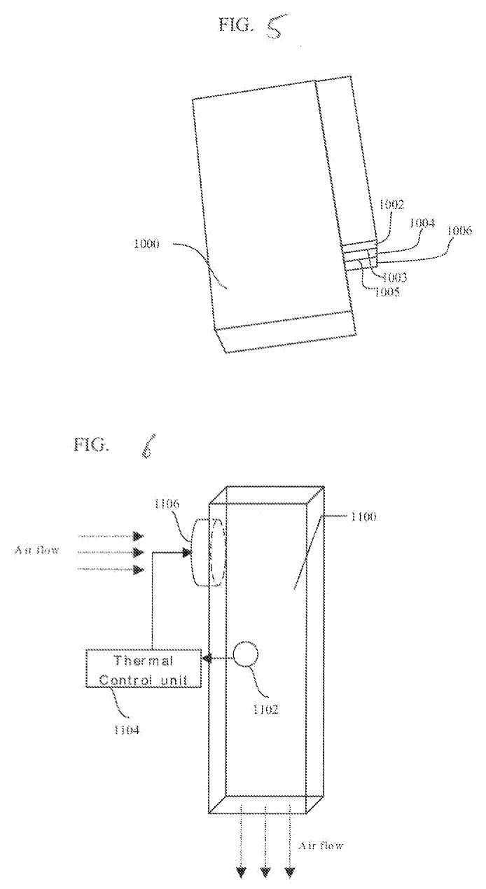

FIG. 4 is an exploded view of an exemplary duct 900 with two fans 920, 922, one speaker 926, and one microphone 928, in accordance with some demonstrative embodiments.

In some demonstrative embodiments, the microphone, or microphones, may be located external to the duct.

In some demonstrative embodiments, the duct 900 may include a generally rectangular box having four sidewalls 902, 904, 906, 908, a closed end 910, and an open end 912. The sidewall 902 of the duct 900 is shown exploded away from the remaining three walls 904, 906, 908.

In some demonstrative embodiments, fans 920, 922 (auxiliary fans) may be mounted on the wall 902 of the duct 900. The sidewall 902 is also provided with a speaker hole 924. A speaker, mounted in a speaker chamber 926, is mounted on an external surface of the one wall, and directs sound through the speaker hole, into the duct, for ANC.

In some demonstrative embodiments, the duct 900, or a number of ducts 900 may be mounted to the rear panel (622) of a rack (600), as illustrated in FIG. 5.

FIG. 5 illustrates three ducts 1002, 1004, 1006, such as the duct 900, installed on a back panel of a rack 1000. The ducts 1002, 1004 and 1006 may be separated from one another by partitions 1003 and 1005, respectively. Inlet and outlet openings are omitted, for illustrative clarity. This figure is intended to demonstrate that multiple ducts can be installed on the back panel of a rack, and they need not extend completely from the top to the bottom of the rack.

In an embodiment, three ducts may be installed in a “drawer-like” manner, sliding in (for installation) and out (for removal, perhaps for maintenance) of corresponding openings in a surface of a rack. This embodiment may include a rack with 2 drawer-like cooling units (on the top and the bottom of the rack) with 3 ducts in each unit. Each unit comprises a fan and an ANC system, as described above.

In some demonstrative embodiments, a method of soundproofing a rack may include installing at least one duct inside the rack in fluid communication with one or more of the rack panels in such a way that air can flow outside from the rack; causing air to flow from the rack through the duct; and providing an active noise control (ANC) system at least partially within the duct.

In some demonstrative embodiments, a soundproof, climate-controlled rack may include a drawer-like unit including one or more ducts which may be installed in the rack as any other device, basically as the upper device and/or the lower device, in fluid communication with one or more external panels; the rack may be configured to cause air to flow from the rack through the duct; and an active noise control (ANC) system disposed at least partially in the duct.

There has thus been shown, in the various embodiments presented herein, techniques for soundproofing a rack by installing at least one duct on at least one panel of the rack, or as part of the side panels of the rack, for example, two ducts as part of the front panel for air inlet and two ducts as part of the back panel for air outlet, or is mounted inside the rack as a drawer with a sort of contact to one or more of the rack panels in such a way that air can flow outside from the rack causing air to flow from the rack through the duct, and providing an active noise control (ANC) system within the duct. Passive noise control may also be provided in the duct. At least one fan may be provided at an inlet of the duct. Fan speed may be controlled, in response to a climactic condition within the rack. The duct may include a back panel, which is added on or a replacement for an existing back panel of the rack. A muffled inlet may be provided on another external surface of the rack.

In some demonstrative embodiments, there is also provided a method for reducing the effects of a noise source and for controlling the climate at a predefined space, such as a rack, closet, cabinet or any other storage means for computer(s) or other related equipment. The method may include generating an input signal from a sensed acoustic noise field generated by a noise source, generating an acoustic output field that is effective to reduce the level of the acoustic noise field, adjusting the input signal generated by an input transducer to compensate for the non linear characteristics of the input transducer, removing extraneous signals from the input signal so as to generate a signal corresponding to substantially the noise source alone and generating an antinoise signal opposite in phase to the input signal, and generating the acoustic output field from the antinoise signal. The method may include computing a fan speed according to a measured temperature level and setting the fans.

In some demonstrative embodiments, controlling the climate may be performed for example using controllable fan operation regarding temperature, pressure, fan failures and humidity. Reducing the effects of a noise source may include any method or combination of methods disclosed herein and/or known to a person of a skill in art. The various methods may be performed by a controller, a microprocessor, a microcontroller or the like, which may be associated with various elements of the system.

FIG. 6 illustrates a method for reducing the effects of a noise source, in accordance with some demonstrative embodiments.

Three processes are illustrated, and are referred to as “Process 1”, “Process 2”, and “Process 3”.

As indicated at block 1202, the method may include achieving (acquiring) one sample from the reference microphone (s[n]).

As indicated at block 1204, the method may include subtracting the EC output [Ey[n] from s[n] to achieve x[n].

In some demonstrative embodiments, the operations of blocks 1202 and 1204 may be common to all three processes (Process 1, Process 2, Process 3).

In Process 1, as indicated at block 1206, the method may include computing the value of y[n] by convolving x[n] with the PF coefficients (FIR filter).

In Process 1, as indicated at block 1208, the method may include emitting the output sample y[n] to the speaker.

In Process 1, the method may include looping back to the operation of block 1202 to achieve another sample from the reference microphone.

In Process 2, as indicated at block 1210, the method may include computing the EC output (Ey[n]) by convolving y[n] with the EC coefficients (FIR filter), and provide the result to step 1204, as shown. This step may be utilized to estimate and to subtract the destructive noise that is sensed by the reference microphone as a surplus signal. The optimal situation is that the reference microphone senses the source signal only, but the real situation is sensing the destructive signal from the speaker also.

Process 3 is may differ from Process 1 and Process 2 in that it does not loop back.

As indicated at block 1212, the method may include computing the correct EC coefficients according to a suitable LMS formula. This step may be utilized to track changes in time in the transfer function of the speaker and of the space between the speaker and the reference microphone.

As indicated at block 1214, the method may include computing the estimated error noise (mt[n]) by convolving x[n] with the MTF coefficients (FIR filter).

As indicated at block 1216, the method may include adding mt[n] to st[n] to have the estimated residual noise in the error microphone err[n].

As indicated at block 1218, the method may include computing the correct PF coefficients according to the LMS formula. These steps may be utilized to track changes in time in the noise signal characteristic and hence to adjust the required destructive noise.

As indicated at block 1220, the method may include computing the estimated counter noise (st[n]) by convolving s[n] with the STF coefficients (FIR filter). Then, the operation of 1216, as already described, may be performed. These steps may be utilized to compute the correction of the PF coefficients, e.g., using any suitable XLMS algorithm.

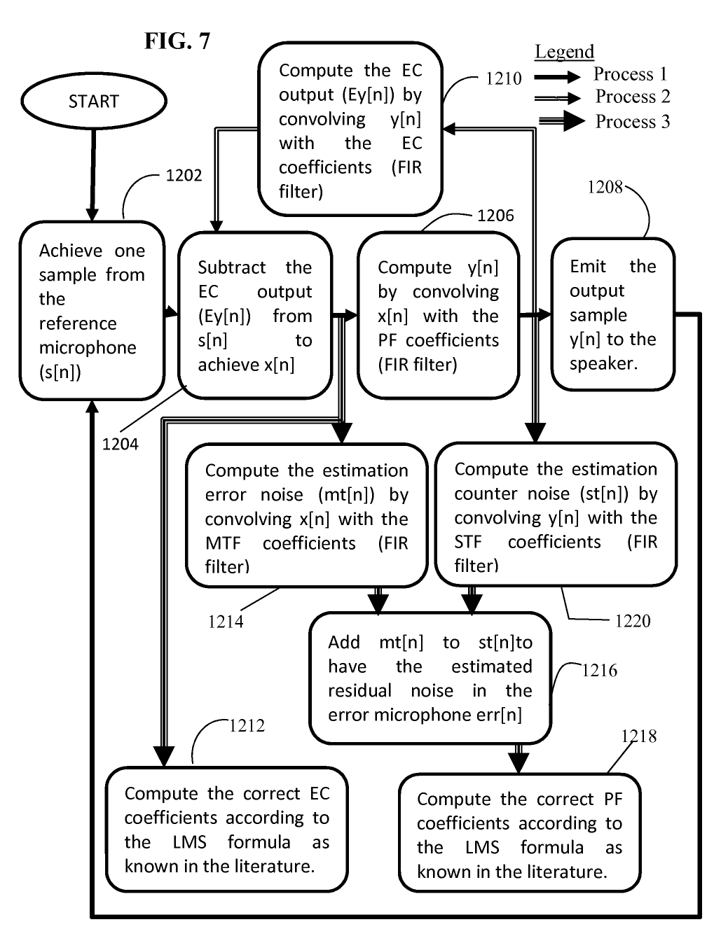

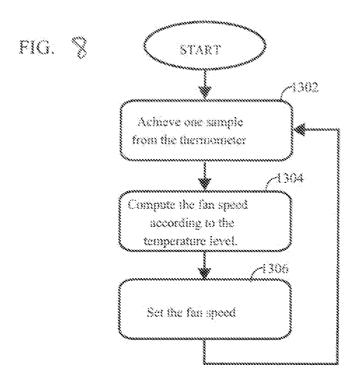

FIG. 7 illustrates a thermal control unit. A thermostat 1102 may be provided in the duct 1100, and a thermal control unit 1104 may be used to control the speed of a fan/blower 1106, to regulate air temperature. The duct 1100 may be similar to the ducts 624, 900, 1002, 1004 and/or 1006 described hereinabove. The thermal control unit 1104 may be integrated in the control system 636.

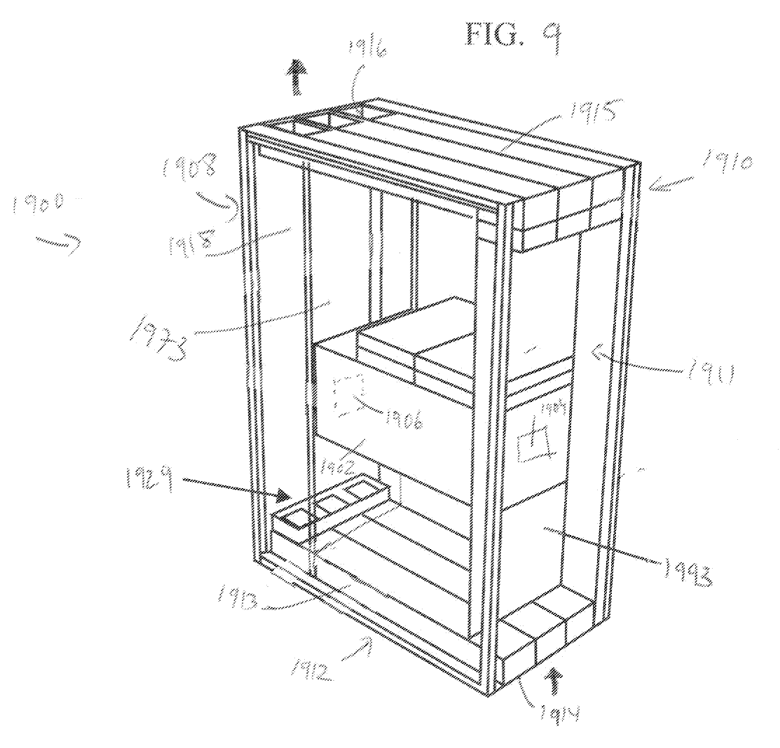

FIG. 8 is a flow chart of a method for thermal control, in accordance with some demonstrative embodiments.

A signal is acquired (block 1302) from the thermostat 1102, which is indicative of the temperature within a cabinet, e.g., rack 600 (FIG. 1). An appropriate speed for the fan 1106 is computed (block 1304) according to the temperature level, and the speed is set (block 1306). The fan speed is controlled in response to a climactic condition within the rack, e.g., temperature.

FIG. 9 is a schematic block diagram illustration of a rack 1900, in accordance with some demonstrative embodiments.

In some demonstrative embodiments, rack 1900 may include and/or utilize one or more of the methods, elements, systems and/or techniques described above, e.g., with reference to Rack 600 (FIG. 1).

In some demonstrative embodiments, rack 1900 may include a muffled rack configured to maintain at least one electronic device, 1902, e.g., a server or a blade server. Device 1902 may include an inlet 1906 to receive air for cooling device 1902 and an outlet 1904 to discharge the air.

In some demonstrative embodiments, rack 1900 may include a first rack portion 1908 configured to surround at least the inlet 1906 of the device 1902, e.g., as described in detail below.

In some demonstrative embodiments, rack 1900 may include a second, muffled, rack portion 1912 to convey cooling air from at least one rack air inlet 1914 into first rack portion 1908 and to muffle noise emanating from within the rack 1900 through the rack air inlet 1914, e.g., as described in detail below.

In some demonstrative embodiments, rack 1900 may include a third, muffled, rack portion 1910 configured to convey the air discharged from the outlet 1904 of the device 1902 to a rack air outlet 1916, e.g., as described in detail below.

In some demonstrative embodiments, portion 1910 may be configured to reduce mixture of the air discharged from the outlet 1904 of the device 1902 with the cooling air from the rack air inlet 1914, e.g., as described below.

In some demonstrative embodiments, portion 1910 may be configured to muffle noise emanating from within the rack 1900 through the rack air outlet 1916.

In some demonstrative embodiments, rack portions 1908, 1910 and/or 1912 may be configured to cause the cooling air to flow from the rack air inlet 1914, through the second, muffled, rack portion 1912, through the first rack portion 1908, and into the inlet 1906 of the device 1902; and to cause the air discharged from the outlet 1904 of the device 1902 to flow through the third, muffled, rack portion 1910 and out of the rack air outlet 1916, e.g., as described in detail below.

In some demonstrative embodiments, rack 1900 may be configured to maintain electronic device 1902 such that inlet 1906 faces a first direction and outlet 1904 faces a second direction. The second rack portion 1912 may include at least one inlet duct 1913 configured to discharge the cooling air into the first rack portion 1908 in a direction substantially perpendicular to the first direction.

In some demonstrative embodiments, rack 1900 may include a first chamber to provide the cooling air to the inlet 1906 of the device 1902; at least one inlet muffled duct to convey the cool air from the rack air inlet into the first chamber and to muffle noise emanating from within the first chamber through the rack air inlet; a second chamber to maintain the air discharged from the outlet 1904 of the device 1902 separate from the air in the first chamber; and at least one outlet muffled duct to convey the air from the second chamber to the rack air outlet and to muffle noise emanating from within the first chamber through the rack air outlet, e.g., as described in detail below.

In some demonstrative embodiments, third rack portion 1910 may include a chamber 1911 separated from the first rack portion 1908. For example, chamber 1911 may be separated from portion 1908 by a suitable plate 1993. Chamber 1908 may be, for example, substantially perpendicular to the inlet duct. Chamber 1908 may be fluidly connected to the outlet 1904 of the device 1902. For example, plate 1993 may be configured to enable air to transfer from outlet 1904 into chamber 1911, while preventing the transfer of air from portion 1908 into chamber 1911.

In some demonstrative embodiments, third rack portion 1910 may include at least one outlet duct 1915, which may be substantially parallel to the inlet duct 1913, to convey air from chamber 1908 to rack air outlet 1916.

In some demonstrative embodiments, first rack portion 1908 may be configured to surround the device 1902.

In some demonstrative embodiments, portion 1908 may be configured as a first chamber 1918 to maintain device 1902, and duct 1913 may be configured to convey the cool air from the rack air inlet 1914 into chamber 1918 and to muffle noise emanating from within chamber 1918 through rack air inlet 1914.

In some demonstrative embodiments, chamber 1918 may be configured to maintain device 1902 at a predefined orientation such that inlet 1906 faces a first predefined direction, and inlet duct 1913 may be configured to discharge the cool air at a second direction, substantially perpendicular to the first direction.

In some demonstrative embodiments, inlet duct 1913 and outlet duct 1915 may be located on opposite sides of chamber 1918, and chamber 1911 may be perpendicular to inlet duct 1913 and outlet duct 1915.

In some demonstrative embodiments, rack air inlet 1914 and rack air outlet 1916 are positioned on different sides of rack 1900. In one example, rack air inlet 1914 and rack air outlet 1916 are positioned on opposite sides of rack 1900.

In some demonstrative embodiments, rack 1900 may include at least one fan 1929 to convey the cool air from rack air inlet 1914 into chamber 1918.

In some demonstrative embodiments, rack 1900 may include at least one fan 1929 to convey the air from chamber 1911 to rack air outlet 1916.

In some demonstrative embodiments, rack 1900, e.g., at least one of ducts 1913 and 1915 may include an active noise cancellation (ANC) system, e.g., as described above.

Some embodiments are described above with reference to a rack, e.g., rack 1900, including an inlet chamber, e.g., e.g., chamber 1918, to maintain a device, e.g., device 1902 such that the inlet of the device, e.g., inlet 1906, is within the chamber; inlet ducts, e.g., ducts 1913 to provide cooling air into the chamber directed toward the inlet of the device; an outlet chamber, e.g., chamber 1911, separated from the inlet chamber, to receive the air discharged from an outlet of the device, e.g., outlet 1904; and ducts, e.g., ducts 1915, to covey the discharged air to an air outlet of the rack. However, in other embodiments, a rack may include any other suitable configuration and/or combination of one or more chambers, one or more inlet ducts, and/or one or more outlet ducts. In one example, a rack may include a, which may be configured to convey the cooling air in a direction opposite to the direction the air is conveyed through rack 1900. For example, rack 1900 may be modified such as to maintain device 1902 in a rotated orientation, e.g., by 180 degrees, such that inlet 1906 faces chamber 1918, which may perform the functionality of an inlet chamber, and outlet 1904 is maintained within chamber 1918, which may perform the functionality of an output chamber. Accordingly, outlet 1916 may be operated as an inlet and ducts 1915 may be operated as inlet ducts to convey air to chamber 1911; and ducts 1913 may be operated as outlet ducts to convey air out from chamber 1918. According to this example, the cooling air may flow from top to bottom, e.g., through ducts 1915 into chamber 1911 and into the inlet of the device. The air discharged from the outlet of the device may flow through chamber 1918 and through ducts 1913.

Some embodiments are described herein with reference to a rack, e.g., rack 1900, including two chambers, e.g., chambers 1911 and/or 1918, separated by a wall or plate, e.g., plate 1993. However, in other embodiments, the rack may include any other suitable number of chambers having any suitable configuration and/or shape and/or separated by any suitable number of plates and/or walls. For example, rack 1900 may include a plate 1973, e.g., in addition to or instead of plate 1993, for example, if rack 1900 is configured to receive the cooling air through inlet 1914, e.g., as described above. According to this example, plate 1973 may be configured to confine chamber 1918 such that chamber 1918 may be fluidly connected to inlet 1906 and may maintain the cooling air from ducts 1913 within chamber 1973, e.g., separate from any other within other portions of rack 1900. For example, chamber 1918 may include only the cooling air, which may not be allowed to mix with air surrounding device 1902. Chamber 1918 may be configured such that inlet 1906 may receive only the cooling air provided by ducts 1913. In one example, plate 1993 may optionally be removed, e.g., such that chamber 1993 extends until plate 1973. In another example, plate 1993 may be maintained and/or located along device 1902 to form chamber 1993 for maintaining the air discharged from outlet 1904.

Functions, operations, components and/or features described herein with reference to one or more embodiments, may be combined with, or may be utilized in combination with, one or more other functions, operations, components and/or features described herein with reference to one or more other embodiments, or vice versa.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

1. A muffled rack configured to maintain at least one electronic device, wherein the electronic device has an inlet to receive air for cooling the electronic device and an outlet to discharge the air, the rack comprising:
a first rack portion configured to surround at least the inlet of the device;
a second, muffled, rack portion fluidly connected to the first rack portion to convey cooling air from a rack air inlet into said first rack portion and to muffle noise emanating from within the rack through the rack air inlet; and
a third, muffled, rack portion configured to convey the air discharged from the outlet of the device to a rack air outlet, and to muffle noise emanating from within the rack through the rack air outlet.

2. The rack of claim 1, wherein the first, second and third rack portions are configured to cause the cooling air to flow from the rack air inlet, through the second, muffled, rack portion, through the first rack portion, and into the inlet of the device; and to cause the air discharged from the outlet of the device to flow through the third, muffled, rack portion and out of the rack air outlet.

3. The rack of claim 1, wherein the rack is configured to maintain the electronic device such that the inlet of the device faces a first direction and a the outlet of the device faces a second direction, wherein the second rack portion includes at least one inlet duct configured to discharge the cooling air into the first rack portion in a direction substantially perpendicular to the first direction.

4. The rack of claim 3 including:
a chamber substantially perpendicular to the inlet duct and fluidly connected to the outlet of the device; and
at least one outlet duct substantially parallel to the inlet duct to convey air from the chamber to the rack air outlet.

5. The rack of claim 3, wherein the first rack portion comprises a chamber substantially perpendicular to the inlet duct and fluidly connected to the inlet of the device.

6. The rack of claim 1, wherein the first rack portion is configured to surround the device.

7. The rack of claim 1 including a fan to convey the air discharged from the outlet of the device into the third rack portion.

8. The rack of claim 1, wherein the rack air inlet and the rack air outlet are positioned on different sides of the rack.

9. The rack of claim 7, wherein the rack air inlet and the rack air outlet are positioned on opposite sides of the rack.

10. The rack of claim 1, wherein at least one of the second and third rack portions includes a duct.

11. The rack of claim 1, wherein at least one of the second and third rack portions include an active noise cancellation (ANC) system.

12. A muffled rack configured to maintain at least one electronic device, wherein the electronic device has an inlet to receive air for cooling the electronic device and an outlet to discharge the air, the rack comprising:
a rack air inlet to receive cooling air;
a rack air outlet to discharge air from the rack;
a first chamber to provide the cooling air to the inlet of the device;
at least one inlet muffled duct to convey the cool air from the rack air inlet into the first chamber and to muffle noise emanating from within the first chamber through the rack air inlet;
a second chamber to maintain the air discharged from the outlet of the device separate from the air in the first chamber; and
at least one outlet muffled duct to convey the air from the second chamber to the rack air outlet and to muffle noise emanating from within the first chamber through the rack air outlet.

13. The rack of claim 12, wherein the first chamber is configured to maintain the device at a predefined orientation such that the inlet of the device faces a first predefined direction, and wherein the inlet duct is configured to discharge the cool air at a second direction, substantially perpendicular to the first direction.

14. The rack of claim 12, wherein the inlet and outlet ducts are located on opposite sides of the first chamber, and wherein the second chamber is perpendicular to the inlet and outlet ducts.

15. The rack of claim 12, wherein the rack air inlet and the rack air outlet are positioned on different sides of the rack.

16. The rack of claim 15, wherein the rack air inlet and the rack air outlet are positioned on opposite sides of the rack.

17. The rack of claim 12 including at least one fan to convey the cool air from the rack air inlet into the first chamber.

18. The rack of claim 12 including at least one fan to convey the air from the second chamber to the rack air outlet.

19. The rack of claim 12, wherein at least one of the inlet and outlet ducts includes an active noise cancellation (ANC) system.

20. The rack of claim 12, wherein the at least one electronic device includes at least one server.
